(19) United States
(12) Patent Application Publication
(10) Pub. No.: US 2018/0330929 A1
(43) Pub. Date: Nov. 15, 2018

(54) IN-SITU REMOVAL OF ACCUMULATED PROCESS BYPRODUCTS FROM COMPONENTS OF A SEMICONDUCTOR PROCESSING CHAMBER

(71) Applicant: Applied Materials, Inc., Santa Clara, CA (US)

(72) Inventors: Ranga Rao ARNEPALLI, Andhra Pradesh (IN); Bipin THAKUR, Mumbai (IN); Kevin A. PAPKE, Portland, OR (US); Yogita PAREEK, Sunnyvale, CA (US)

(21) Appl. No.: 15/591,908

(22) Filed: May 10, 2017

(51) Int. Cl. H01J 37/32; C23C 16/44; B08B 7/00

(52) U.S. Cl. CPC H01J 37/32862; H01J 37/32522; B08B 7/0035; C23C 16/4405; H01J 37/32449

(57) ABSTRACT

Embodiments of the disclosure generally relate to methods for removal of accumulated process byproducts from components of a semiconductor processing chamber. In one embodiment of the disclosure, a method for cleaning components within a processing chamber is disclosed. The method includes heating the components within the processing chamber to a temperature between about 150-300 degrees Celsius, exposing the components of the chamber to one or more precursor gases and removing a product of a reaction between a fluorine-based compound disposed on the components and the one or more precursor gases. The one or more precursor gases include trimethyl aluminum or tin acetylacetonate.

### BACKGROUND

### Field

Embodiments of the disclosure generally relate to methods for removal of accumulated process byproducts from components of a semiconductor processing chamber.

### Description of the Related Art

The formation and accumulation of process byproducts on the walls and other components of the semiconductor processing chamber, including the showerhead and the faceplate is a serious issue. For example, formation of aluminum trifluoride (AlFₓ) on the chamber components in the semiconductor processing chamber causes process drifts and particle generation. Formation of AlFₓ on the chamber components is inevitable and AlFₓ keeps on accumulating until the particles flake off within the chamber. AlFₓ is extremely etch resistant. To remove AlFₓ deposits from the chamber components, the components are typically removed from the chamber for wet cleaning, which causes significant chamber downtime.

Thus, there is a need for an improved method for removing process byproducts like AlFₓ.

### SUMMARY

Embodiments of the disclosure generally relate to methods for removal of accumulated process byproducts from components of a semiconductor processing chamber. In one embodiment of the disclosure, a method for cleaning components within a processing chamber is disclosed. The method includes heating the components within the processing chamber to a temperature between about 150-300 degrees Celsius, exposing the components of the chamber to one or more precursor gases, and removing a product of a reaction between a fluorine-based compound disposed on the components and the one or more precursor gases. The one or more precursor gases include trimethyl aluminum or tin acetylacetonate.

In another embodiment of the disclosure, a method for cleaning components within a processing chamber is disclosed. The method includes exposing the components of the chamber to one or more precursor gases, forming a plasma from the one or more precursor gases disposed within the processing chamber and removing a product of a reaction between a fluorine-based compound disposed on the components and the one or more precursor gases. The one or more precursor gases include silicon chloride or chlorine.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a simplified front cross-sectional view of a semiconductor processing chamber.

FIG. 2 is a block diagram of a method for cleaning components within the semiconductor processing chamber using an organometallic compound as a precursor gas.

FIG. 3 is a block diagram of a method for cleaning components within the semiconductor processing chamber using silicon chloride or chlorine or a mixture of both under plasma as a precursor gas.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure generally relate to methods for removal of accumulated process byproducts from components of a semiconductor processing chamber. The process byproducts include fluorine-based compounds, such as metal fluorides and oxyfluorides, which are highly resistant to etching. The embodiments discuss the various processes, conditions and chemistry that allow for the quick removal of the process byproducts and reduction in chamber downtime.

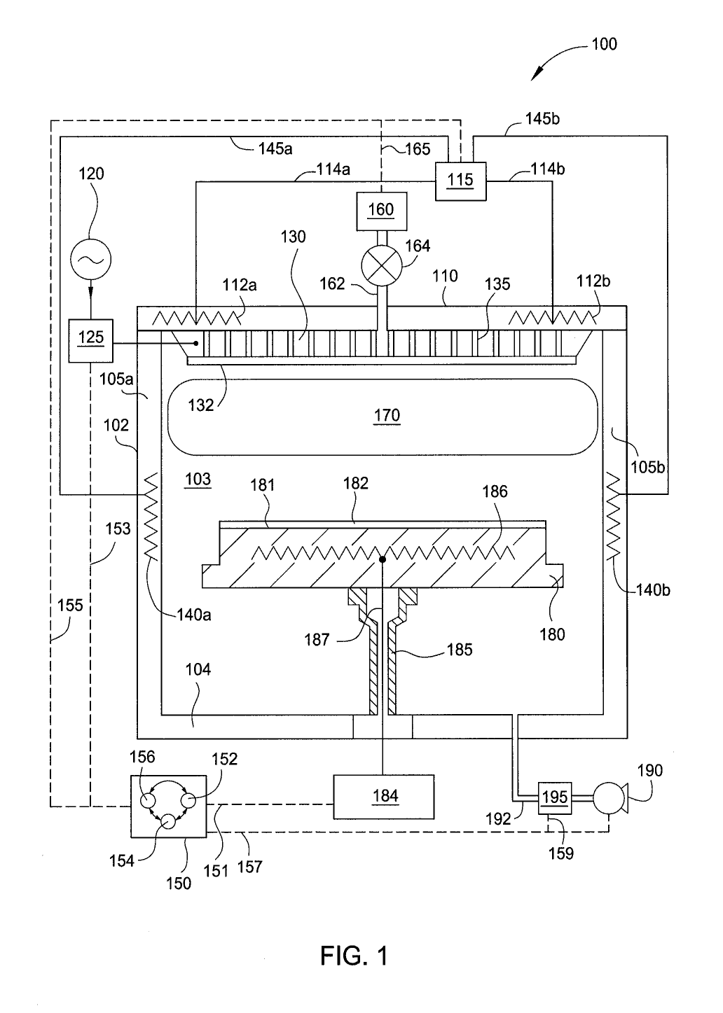

FIG. 1 is a simplified front cross-sectional view of a semiconductor processing chamber 100, according to one embodiment of the disclosure. The semiconductor processing chamber 100 may be a physical vapor deposition (PVD) or a chemical vapor deposition (CVD) processing chamber available from Applied Materials, Inc. of Santa Clara, Calif. The embodiment of the chamber 100 described herein is a CVD chamber. However, it is contemplated that the disclosure described herein can be embodied in other semiconductor processing chambers, such as those for etching, implanting, annealing, and plasma-treating semiconductor substrates, among others.

The semiconductor processing chamber 100 includes a chamber body 102 that encompasses an inner volume 103. The chamber body 102 has sidewalls 105a and 105b, a lid 110 and a bottom wall 104. The sidewalls 105a and 105b, lid 110 and the bottom wall 104 may be formed from conductive materials, such as aluminum or stainless steel. Heating elements 112a and 112b are disposed on the lid 110 and configured to heat the inner volume 103. Heating elements 140a and 140b are disposed on the sidewalls 105a and 105b respectively and configured to heat the inner volume 103. In some embodiments, the heating elements 112a, 112b, 140a and 140b are resistive coils. In other embodiments, one or more of the heating elements 112a, 112b, 140a and 140b are ultraviolet lamps. The ultraviolet lamps have wavelength between about 120 nm to about 190 nm, though in some other embodiments, the ultraviolet lamps have wavelength varying between about 10 nm to about 400 nm. The heating elements and/or ultraviolet lamps 112a, 112b, 140a and 140b are electrically connected to the power supply 115.

A radio-frequency (RF) power source 120 is coupled to the chamber 100 and provides RF power to a showerhead 130 to drive a plasma 170 in the chamber 100. A power source 120 provides RF power to the showerhead 130 up to about 40 kW, and at a frequency between about 1-60 MHz. An RF matching circuit 125 connects the chamber 100 to the RF power source 120.

The showerhead 130 is coupled to the lid 110 and is disposed within the inner volume 103 above a substrate support 180. The showerhead 130 includes a faceplate 132 and a plurality of gas passage holes 135 formed therein. The gas passage holes 135 are configured to receive a gas from a gas panel 160 through a conduit 162 and distribute the gas through the faceplate 132 into the inner volume 103.

The gas panel 160 is fluidly connected by the conduit 162 to provide one or more gases to the inner volume 103 of the chamber 100. A flow controller 164 is coupled between the gas panel 160 and the inner volume 103 to control the gas flow into the inner volume 103. The chamber body 102 is connected to an exhaust pipe 192 which is connected to a pump 190. A gas analyzer 195 is interfaced with the exhaust pipe 192 and configured to detect and measure the characteristics of the gases pumped out of the inner volume 103 of the chamber 100.

The gas analyzer 195 is a metrology tool which can be configured to generate signals/spectra related to the gaseous products formed from the chemical reactions between the precursor gas and the fluorine-based process byproducts disposed on the components of the chamber 100. The spectra from the gaseous products are then utilized to monitor which materials are being removed from the inner volume 103. The chemical species information of the gaseous products generated by the gas analyzer 195 is helpful in determining if there are any differences in concentration of the precursor gases while cleaning the undesirable fluorine-based process byproducts within the chamber 100. The chemical species information is also helpful in determining whether the precursor gases are selectively removing the fluorine-based process byproducts and whether they are affecting other components of the chamber 100 which need to be protected from the precursor gases. The gas analyzer 195 may be a Residual Gas Analyzer (RGA) or a Fourier Transform InfraRed spectrometer (FTIR). The RGA uses mass spectrometry to monitor the concentration of the gases exiting the inner volume 103 through the exhaust pipe 192 and determine when the concentration of the gas in the inner volume 103 has changed. The FTIR uses infrared spectroscopy to measure the concentration of the gases exiting the inner volume 103 through the exhaust pipe 192. For example, when the data from the gas analyzer 195 indicates a reduction or an absence of fluorine-based compounds, it can be inferred that the deposits of fluorine-based compounds have been removed from the components within the chamber 100.

The substrate support 180 is disposed within the inner volume 103 of the chamber 100 for processing a semiconductor substrate 182. The substrate support 180 has a support surface 181 held by a stem 185. The semiconductor substrate 182 is disposed on the support surface 181. The substrate support 180 has a heater 186 disposed within, which is configured to heat the substrate 182 during processing. The heater 186 is electrically connected to a power supply 184 through a wire 187 passing through the stem 185.

A controller 150 is connected to the chamber 100. The controller 150 regulates the power supply 184 connected to the heater 186 within the substrate support 180. The controller 150 also regulates the power supply 115, the RF power source 120, the gas panel 160, the pump 190 and the gas analyzer 195. The controller 150 includes a central processing unit (CPU) 152, a memory 154, and a support circuit 156. The CPU 152 is any form of a general-purpose computer processor that may be used in an industrial setting. Software routines are stored in the memory 154, which may be a random access memory, a read-only memory, floppy, a hard disk drive, or other form of digital storage. The support circuit 156 is conventionally coupled to the CPU 152 and may include cache, clock circuits, input/output systems, power supplies, and the like.

The semiconductor processing chamber 100 is advantageously cleaned in-situ by utilizing different chemistries to remove fluorine-based process byproducts from the chamber components. The components of the chamber 100 have one or more fluorine-based process byproducts disposed thereon as residue. The fluorine-based process byproducts may include one or more of aluminum fluoride, yttrium fluoride, hafnium fluoride, zirconium fluoride, aluminum oxyfluoride, yttrium oxyfluoride, hafnium oxyfluoride, and zirconium oxyfluoride. The fluorine-based process byproducts may cause process drifts and particle generation, and thus are periodically removed as described below using the cleaning process. During the cleaning process, the substrate 182 is first removed from the chamber 100. One or more of the heating elements and/or ultraviolet lamps 105a, 105b, 140a and 140b are operated by providing power from the power supply 115. The surfaces of the chamber components exposed to the inner volume 103 of the chamber 100 are heated to a temperature of between about 150-300 degrees Celsius by operating one or more of the heating elements 105a, 105b, 140a and 140b. The components of the chamber 100, such as but not limited to the showerhead 130, the faceplate 132, and the substrate support 180, are heated as a result.

At least one precursor gas is provided from the gas panel 160 and travel through the conduit 162 into the inner volume 103. The precursor gas passes through the plurality of gas passage holes 135 in the showerhead 130 and the faceplate 132 into the inner volume 103. Optionally, the precursor gas is delivered into the chamber 100 in pulses such that with each pulse, the pressure in the chamber 100 is raised to between 25 mTorr to 100 mTorr, though in some embodiments, the pressure varies between about 10 mTorr to about 500 mTorr. Optionally, one or more additional gases, such as but not limited to nitrogen or an inert gas like argon, are provided from the gas panel 160 into the inner volume 103 to dilute the concentration of the precursor gas. Optionally, the precursor gas is energized to the plasma 170 by power applied to the showerhead 130 by the RF power source 120. The precursor gas reacts with the fluorine-based process byproducts to form a complex product, which is volatile at temperatures greater than 200 degrees Celsius. When desirable to remove fluorine-based process byproducts at lower temperatures, a plasma of nitrogen or an inert gas like argon is utilized to enable the reaction between about 50 degrees Celsius to about 100 degrees Celsius, though in some embodiments, the temperature varies between 25 degrees Celsius to about 150 degrees Celsius. The products of the reaction are removed from the inner volume 103 through the exhaust pipe 192 by the pump 190. The process is continuously performed or may be repeated several times until all the products of the reaction are removed and the chamber components are clean. The gas analyzer 195 detects the presence of the volatile product of the reaction in the chamber exhaust to determine an endpoint of the reaction and confirm the effective removal of the undesirable fluorine-based process byproducts from the inner volume 103.

In one embodiment of the present disclosure, the precursor gas includes organo-metallic compounds like trimethyl aluminum (TMA), trimethyl gallium (TMG) or tin acetylacetonate (Sn(acac)₂) which effectively react with the fluorine-based process byproducts to form volatile products which are subsequently removed from the chamber.

The selection of organo-metallic compounds as precursor gases to react with the fluorine-based process byproducts is effective for the ligand-exchange transmetalation reaction that helps remove the fluorine-based process byproducts from the chamber 100. For example, TMA is an effective metal precursor that accepts fluorine (F) ion from aluminum trifluoride (AlF₃) layer and donates methyl (CH₃) ligand to the AlF₃ layer to produce dimethyl aluminum fluoride (AlF(CH₃)₂) as a volatile product of the reaction. TMA exposure also produces other fluorine-containing species such as methyl aluminum difluoride (AlF₂(CH₃)*) surface species, which are removed by additional TMA exposure.

Sn(acac)₂ is another effective metal precursor for the ligand-exchange transmetalation reaction. The Sn(acac)₂ accepts fluorine (F) ion from AlF₃ layer and donates acetylacetonate (acac) ligand to the AlF₃ layer to produce tin fluoride acetylacetonate (SnF(acac)) and aluminum fluoride acetylacetonate (AlF(acac)₂) as volatile products of the reaction. In addition, the Sn(acac)₂ exposure also produces aluminum difluoride acetylacetonate (AlF₂(acac)*) surface species which are removed by additional exposure to Sn(acac)₂.

In a second embodiment of the present disclosure, the precursor gas includes either silicon chloride (SiClₓ) or chlorine (Cl₂) or a mixture of both under plasma. When the chamber components are exposed to the chlorine radical/ions, alone or in combination under plasma, the chlorine radicals/ions effectively react with the various fluorine-based process byproducts to make volatile products such as aluminum chloride (AlCl₃/Al₂Cl₆) and silicon fluoride (SiF₄). The reaction occurs at moderate temperatures between about room temperature (22 degrees Celsius) to about 100 degrees Celsius, though in some embodiments, the temperature varies between about 25 degrees Celsius to about 150 degrees Celsius. An inert gas like argon is used to dilute the precursor gas to prevent damage to other chamber components where there is substantially no formation of fluorine-based process byproducts. The formation of aluminum chloride (AlCl₃/Al₂Cl₆) and silicon fluoride (SiF₄) from AlFₓ is an endothermic reaction that absorbs heat energy of about 212 kJ/mole (for formation of AlCl₃) and 148 kJ/mole (for formation of Al₂Cl₆). Silicon-containing ions that impinge on the reactor components with a mean energy of 15 eV, assists in the formation of the volatile products like aluminum chloride (AlCl₃/Al₂Cl₆) and silicon fluoride (SiF₄). The entire process can be performed in less than 30 seconds as a maintenance step in between processing substrates.

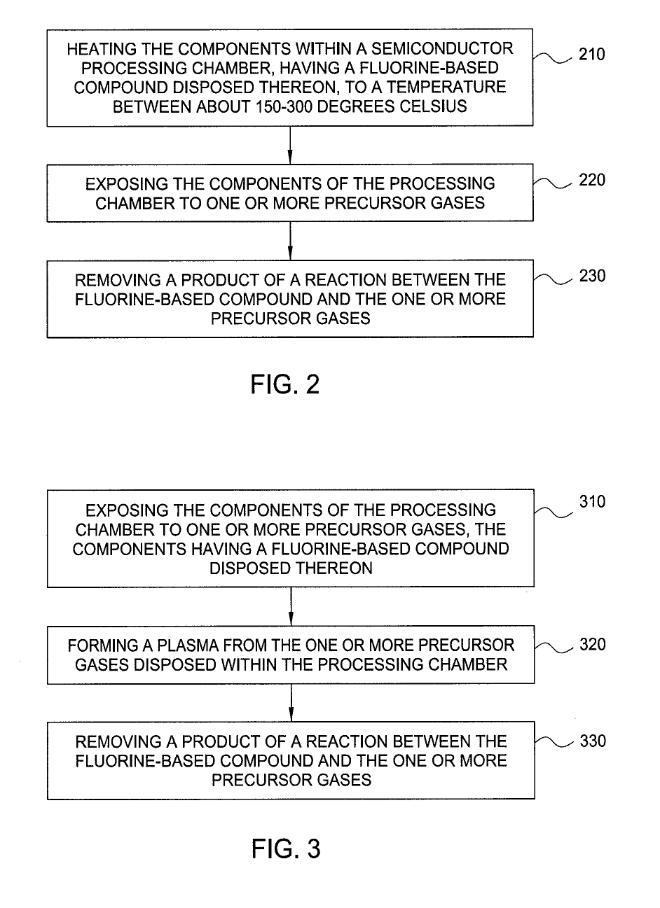

FIG. 2 is a block diagram of a method 200 for cleaning components within the semiconductor processing chamber using an organometallic compound as a precursor gas, according to one embodiment of the present disclosure. The method 200 begins at block 210 by heating the components within the semiconductor processing chamber to a temperature between about 150-300 degrees Celsius. The components may be heated utilizing the heating elements disposed in the sidewalls and the lid of the chamber. The components of the semiconductor processing chamber, such as the showerhead and the faceplate, have fluorine-based process byproducts disposed thereon. The fluorine-based process byproducts may be one or more of aluminum fluoride, yttrium fluoride, hafnium fluoride, zirconium fluoride, aluminum oxyfluoride, yttrium oxyfluoride, hafnium oxyfluoride, and zirconium oxyfluoride.

At block 220, the components of the semiconductor processing chamber are exposed to one or more organometallic compounds as precursor gases. The precursor gases may be trimethyl aluminum (TMA) or tin acetylacetonate (Sn(acac)₂), which are pulsed into the chamber from a gas panel connected to the showerhead. The gas flow varies depending on the volume of the chamber. The chamber pressure is maintained between about 100 mTorr to between about 1 Torr for each gas, though in some embodiments, the chamber pressure varies between about 20 mTorr to about 10 Torr. The temperature of the chamber is maintained between about 150 degrees Celsius to about 300 degrees Celsius, though in some embodiments, the temperature varies between about 75 degrees Celsius to about 350 degrees Celsius.

When TMA is utilized as a precursor gas, it reacts with the fluorine-based process byproducts to form dimethyl aluminum fluoride as a product of the reaction. When Sn(acac)₂ is utilized as a precursor gas, it reacts with the fluorine-based process byproducts to form tin fluoride acetylacetonate and aluminum fluoride acetylacetonate as products of the reaction. In some embodiments, a plasma is formed from argon or nitrogen within the processing chamber; the chamber components can be maintained at a temperature of less than about 150 degrees Celsius during the reaction. In other embodiments, the components of the processing chamber are exposed to ultraviolet light such that chamber can be maintained at a temperature of less than about 150 degrees Celsius during the reaction. Exposure to ultraviolet light is enabled by the presence of ultraviolet lamps on the chamber body. The fluorine-based process byproducts disposed on the components of the chamber absorb the ultraviolet light and decompose into volatile products.

At block 230, the products of the reaction between the fluorine-based process byproducts and the one or more precursor gases are removed from the semiconductor processing chamber. An end-point of the reaction is determined by detecting the presence of the product of the reaction in the effluent exiting the chamber. A gas analyzer such as but not limited to, an RGA or an FTIR is used for that purpose.

FIG. 3 is a block diagram of a another method 300 for cleaning components within the semiconductor processing chamber using one or more precursor gases under plasma, according to one embodiment of the present disclosure. The method 300 begins at block 310 by exposing the components of the semiconductor processing chamber to one or more precursor gases. The precursor gases may be silicon chloride (SiCl₄), chlorine (Cl₂) or a mixture of both which is delivered into the chamber from a gas panel connected to the showerhead. The gas flow varies depending on the volume of the chamber. The chamber pressure is maintained between about 25 mTorr to between about 100 mTorr for each gas, though in some embodiments, the chamber pressure varies between about 10 mTorr to about 500 mTorr. The temperature of the chamber is maintained between about 50 degrees Celsius to about 100 degrees Celsius, though in some embodiments, the temperature varies between about 25 degrees Celsius to about 150 degrees Celsius. The plasma is maintained at a power between about 400 Watts to about 600 Watts, though in some embodiments, the plasma power varies up to 800 Watts. The bias voltage is maintained ay a power between about 100 Watts to about 150 Watts, though in some embodiments, the power to the bias voltage varies up to 300 Watts.

The components of the semiconductor processing chamber, such as the showerhead and the faceplate have a fluorine-based process byproducts disposed thereon. The fluorine-based process byproducts may be one or more of aluminum fluoride, yttrium fluoride, hafnium fluoride, zirconium fluoride, aluminum oxyfluoride, yttrium oxyfluoride, hafnium oxyfluoride, and zirconium oxyfluoride. The one or more precursor gases is delivered into the chamber from a gas panel connected to the showerhead.

At block 320, a plasma is formed from the one or more precursor gases. In some embodiments, an additional gas is added to dilute the concentration of the one or more precursor gases used to form the plasma. The additional gas may be nitrogen, or an inert gas such as argon. When silicon chloride, chlorine or a mixture of both is utilized as a precursor gas, it reacts with the fluorine-based process byproducts to form aluminum chloride and silicon fluoride as products of the reaction.

At block 330, the products of the reaction between the fluorine-based process byproducts and the one or more precursor gases are removed from the semiconductor processing chamber. An end-point of the reaction is determined by detecting the presence of the product of the reaction. A gas analyzer such as but not limited to, an RGA or an FTIR is used for that purpose.

The present disclosure provides an improved method for cleaning a semiconductor processing chamber by removing process byproducts in-situ. As a result, chamber downtime is reduced and operational time of the chamber is effectively increased. Thus the improved method ensures that there is no non-uniformity between batches of substrates and that the substrates are free from particle generation, without having to compromise on the operational continuity of the chamber.

While the foregoing is directed to particular embodiments of the present disclosure, it is to be understood that these embodiments are merely illustrative of the principles and applications of the present invention. It is therefore to be understood that numerous modifications may be made to the illustrative embodiments to arrive at other embodiments without departing from the spirit and scope of the present inventions, as defined by the appended claims.

1. A method for cleaning components within a processing chamber, the method comprising:
heating the components within the processing chamber to a temperature between about 150-300 degrees Celsius;
exposing the components of the processing chamber to one or more precursor gases, the precursor gases comprising trimethyl aluminum or tin acetylacetonate; and
removing a product of a reaction between a fluorine-based compound disposed on the components and the one or more precursor gases.

2. The method of claim 1, wherein the fluorine-based compound comprises one or more of:
aluminum fluoride, yttrium fluoride, hafnium fluoride, zirconium fluoride, aluminum oxyfluoride, yttrium oxyfluoride, hafnium oxyfluoride, and zirconium oxyfluoride.

3. The method of claim 1 further comprising:
pulsing the one or more precursor gases into the processing chamber.

4. The method of claim 1, wherein the product of the reaction comprises dimethyl aluminum fluoride upon using trimethyl aluminum as the precursor gas.

5. The method of claim 1, wherein the product of the reaction comprises tin fluoride acetylacetonate and aluminum fluoride acetylacetonate upon using tin acetylacetonate as the precursor gas.

6. The method of claim 1, wherein exposing the components of the processing chamber to one or more precursor gases further comprises:
forming a plasma from the one or more precursor gases disposed within the processing chamber.

7. The method of claim 6, wherein the plasma is formed from argon or nitrogen.

8. The method of claim 1, wherein exposing the components of the processing chamber to one or more precursor gases further comprises:
exposing the components of the processing chamber to ultraviolet light.

9. The method of claim 6, wherein the chamber is maintained at a temperature of less than about 150 degrees Celsius.

10. The method of claim 1 further comprising:
detecting the presence of the product of the reaction to determine an endpoint of the reaction.

11. A method for cleaning components within a processing chamber, the method comprising:
exposing the components of the processing chamber to one or more precursor gases comprising silicon chloride or chlorine;
forming a plasma from the one or more precursor gases disposed within the processing chamber; and
removing a product of a reaction between a fluorine-based compound disposed on the components and the one or more precursor gases.

12. The method of claim 11 further comprising:
adding an additional gas to dilute concentration of the one or more precursor gases.

13. The method of claim 12, wherein the additional gas is argon or nitrogen.

14. The method of claim 11, wherein the fluorine-based compound comprises one or more of:
aluminum fluoride, yttrium fluoride, hafnium fluoride, zirconium fluoride, aluminum oxyfluoride, yttrium oxyfluoride, hafnium oxyfluoride, and zirconium oxyfluoride.

15. The method of claim 11, wherein the product of the reaction comprises:
aluminum chloride and silicon fluoride.

16. The method of claim 8, wherein the chamber is maintained at a temperature of less than about 150 degrees Celsius.
